(19) United States
(12) Patent Application Publication
(10) Pub. No.: US 2014/0138243 A1
(43) Pub. Date: May 22, 2014

(54) IN-LINE DEPOSITION SYSTEM WITH ENHANCED ADHESION OF MOLYBDENUM ON BOTTOM SHIELD

(71) Applicant: Stion Corporation, San Jose, CA (US)

(72) Inventors: Rajiv Pethe, Sunnyvale, CA (US); Robert D. Wieting, Simi Valley, CA (US)

(21) Appl. No.: 14/083,181

(22) Filed: Nov. 18, 2013

Related U.S. Application Data
(60) Provisional application No. 61/728,221, filed on Nov. 19, 2012.

(51) Int. Cl. H01L 31/18

(52) U.S. Cl. CPC H01L 31/18
USPC 204/298.11

(57) ABSTRACT

An in-line sputtering system includes a chamber and a sputtering target near a top region of the chamber. The system also includes a moving device located on a bottom region of the chamber configured to move a plurality of planar substrates loaded horizontally in a row with at least a gap distance between any neighboring substrates, The gap distance allows the bottom region to be subjected to a deposition from the sputtering target as the gap distance moves across the entire bottom region along with the plurality of planar substrates by the moving device, The system further includes a bottom shield disposed to cover entire bottom region except the moving device and configured to adhere the deposition through the gap distance from the sputtering target for preventing a deposition buildup.

### CROSS-REFERENCES TO RELATED APPLICATIONS

NOT APPLICABLE

### STATEMENT AS TO RIGHTS TO INVENTIONS MADE UNDER FEDERALLY SPONSORED RESEARCH AND DEVELOPMENT

NOT APPLICABLE

### REFERENCE TO A “SEQUENCE LISTING,” A TABLE, OR A COMPUTER PROGRAM LISTING APPENDIX SUBMITTED ON A COMPACT DISK

NOT APPLICABLE

### BACKGROUND OF THE INVENTION

The present invention relates generally to techniques for the manufacture of photovoltaic devices. More particularly, the present invention provides a system for forming thin-film photovoltaic device and a method for enhancing molybdenum adhesion on bottom shield. Merely by way of examples, the present invention is implemented in a sputtering compartment for forming a bottom electrode of thin-film photovoltaic device without causing a buildup of deposited material on the bottom shield, but it would be recognized that the invention may have other applications.

From the beginning of time, mankind has been challenged to find way of harnessing energy. Energy comes in the forms such as petrochemical, hydroelectric, nuclear, wind, biomass, solar, and more primitive forms such as wood and coal. Over the past century, modern civilization has relied upon petrochemical energy as an important energy source. Petrochemical energy includes gas and oil. Gas includes lighter forms such as butane and propane, commonly used to heat homes and serve as fuel for cooking. Gas also includes gasoline, diesel, and jet fuel, commonly used for transportation purposes. Heavier forms of petrochemicals can also be used to heat homes in some places. Unfortunately, the supply of petrochemical fuel is limited and essentially fixed based upon the amount available on the planet Earth. Additionally, as more people use petroleum products in growing amounts, it is rapidly becoming a scarce resource, which will eventually become depleted over time.

More recently, environmentally clean and renewable sources of energy have been desired. An example of a clean source of energy is hydroelectric power. Hydroelectric power is derived from electric generators driven by the flow of water produced by dams such as the Hoover Dam in Nevada. The electric power generated is used to power a large portion of the city of Los Angeles in California. Clean and renewable sources of energy also include wind, waves, biomass, and the like. That is, windmills convert wind energy into more useful forms of energy such as electricity. Still other types of clean energy include solar energy. Specific details of solar energy can be found throughout the present background and more particularly below.

Solar energy technology generally converts electromagnetic radiation from the sun to other useful forms of energy. These other forms of energy include thermal energy and electrical power. For electrical power applications, solar cells are often used. Although solar energy is environmentally clean and has been successful to a point, many limitations remain to be resolved before it becomes widely used throughout the world. As an example, one type of solar cell uses crystalline materials, which are derived from semiconductor material ingots. These crystalline materials can be used to fabricate optoelectronic devices that include photovoltaic and photodiode devices that convert electromagnetic radiation into electrical power. However, crystalline materials are often costly and difficult to make on a large scale. Additionally, devices made from such crystalline materials often have low energy conversion efficiencies. Other types of solar cells use “thin film” technology to form a thin film of photosensitive material to be used to convert electromagnetic radiation into electrical power. Similar limitations exist with the use of thin film technology in making solar cells. In particularly, although many techniques have been applied to form thin film photovoltaic devices based on copper indium gallium diselenide CIGS material, some were still found to be less effective. For example, sputtering deposition is widely used for forming bottom electrode layer of the CIGS based thin film solar device. In-line deposition method is good for large scale manufacture but shows limitation in the sample flow due to certain bottle-neck processes which results in one or more process issues. Therefore, it is desired to provide an improved system and method for performing thin film deposition in an in-line sputtering system, which can be found throughout the present specification.

### BRIEF SUMMARY OF THE INVENTION

The present invention relates generally to techniques for the manufacture of photovoltaic devices. More particularly, the present invention provides a system for forming thin-film photovoltaic device and a method for enhancing molybdenum adhesion on bottom shield. Merely by way of examples, the present invention is implemented in a sputtering compartment for forming a bottom electrode of thin-film photovoltaic device without causing a buildup of deposited material on the bottom shield, but it would be recognized that the invention may have other applications.

In a specific embodiment, the present invention provides an in-line sputtering system for the manufacture of thin film solar devices. The system includes a first vacuum compartment configured to grow a barrier layer overlying both top and bottom surfaces of a first planar substrate. Additionally, the system includes a conveyer comprising a plurality of rollers configured to move a plurality of planar substrates loaded horizontally in a row through the first vacuum compartment. The plurality of planar substrates includes the first planar substrate with at least a gap distance away from a second planar substrate next in the row on the conveyer. Furthermore, the system includes a second vacuum compartment configured to receive the plurality of planar substrates including the first and the second planar substrates from the first vacuum compartment. Each of the plurality of planar substrates has its bottom surface being supported by the rollers to move horizontally under a molybdenum target to have its top surface being coated by a molybdenum layer. Moreover, the system includes a bottom shield disposed on entire bottom region of the second vacuum compartment except a few places for the rollers.

The bottom shield comprises a corrugated surface region subjecting to deposition from the molybdenum target whenever the gap distance between any neighboring planar substrates moves over the bottom shield. Further, the corrugated surface region is configured to adhere substantially the deposited molybdenum layer free of any peel-off effect.

In another specific embodiment, the invention provides an in-line sputtering system. The system includes a chamber and a sputtering target near a top region of the chamber. The system further includes a moving device located on a bottom region of the chamber. The moving device is configured to move a plurality of planar substrates loaded horizontally in a row with at least a gap distance between any neighboring substrates. The gap distance allows the bottom region to be subjected to a deposition from the sputtering target as the gap distance moves across the entire bottom region along with the plurality of planar substrates by the moving device. Furthermore, the system includes a bottom shield disposed to cover entire bottom region except the moving device and configured to adhere substantially the deposition through the gap distance from the sputtering target for preventing a deposition buildup.

Many benefits can be achieved by applying the embodiments of the present invention. The present invention provides an in-line thin film deposition system for large scale manufacture of thin film photovoltaic modules. In particular, the thin-film photovoltaic module is copper-indium-gallium-silenide (CGIS) material based device grown directly on a glass substrate. Embodiments of the present invention are applied to the process of forming base electrodes of the thin film solar modules by sputtering a molybdenum film over a barrier layer that is specifically wrapped around entire surfaces of the glass substrate. A specific embodiment is to dispose a bottom shield made by either a single plate with a roughened top surface region or a double-layer shield having a first grating layer over a second solid plate to cover the bottom member. Such bottom shields enhance adhesion of the sputtering molybdenum deposited through a gap between loaded glass substrates and prevent abnormal buildup the molybdenum material to cause damages to the barrier layer on the bottom surface of the glass substrate that faces the top surface region of the bottom shield. One major benefit of the present invention is to substantially prolong system working time without need of frequent shutting down to replace the bottom shield. The invention provide effective solution to eliminate possible damage to the barrier layer wrapped on the glass which has been proved to be very important for forming a high-performance CIGS material based thin-film photovoltaic module. These and other benefits may be described throughout the present specification and more particularly below.

### BRIEF DESCRIPTION OF THE DRAWINGS

FIG. 1 is a simplified schematic diagram of an in-line thin-film deposition system according to an embodiment of the present invention;

FIG. 2 is simplified schematic diagram showing a row of planar substrates being moved by a conveyer associated with the in-line thin-film deposition system in FIG. 1 according to an embodiment of the present invention;

FIG. 3 is a simplified schematic diagram of a sputtering compartment with two moving planar substrates in load positions above a bottom shield according to an embodiment of the present invention;

FIG. 4 is a simplified diagram showing an exemplary bi-layer bottom shield disposed in the sputtering compartment in FIG. 3 according to an embodiment of the present invention;

FIG. 5 is a simplified diagram showing an exemplary bi-layer bottom shield disposed in the sputtering compartment in FIG. 3 according to another embodiment of the present invention; and

FIG. 6 is a simplified diagram showing a roughened bottom shield disposed in the sputtering compartment in FIG. 3 according to another embodiment of the present invention.

### DETAILED DESCRIPTION OF THE INVENTION

The present invention relates generally to techniques for the manufacture of photovoltaic devices. More particularly, the present invention provides a system for forming thin-film photovoltaic device and a method for eliminating target material deposition buildup. Merely by way of examples, the present method implements a sputtering compartment for forming bottom electrode of thin-film photovoltaic device without causing seed layer to build up in the bottom shield, but it would be recognized that the invention may have other applications.

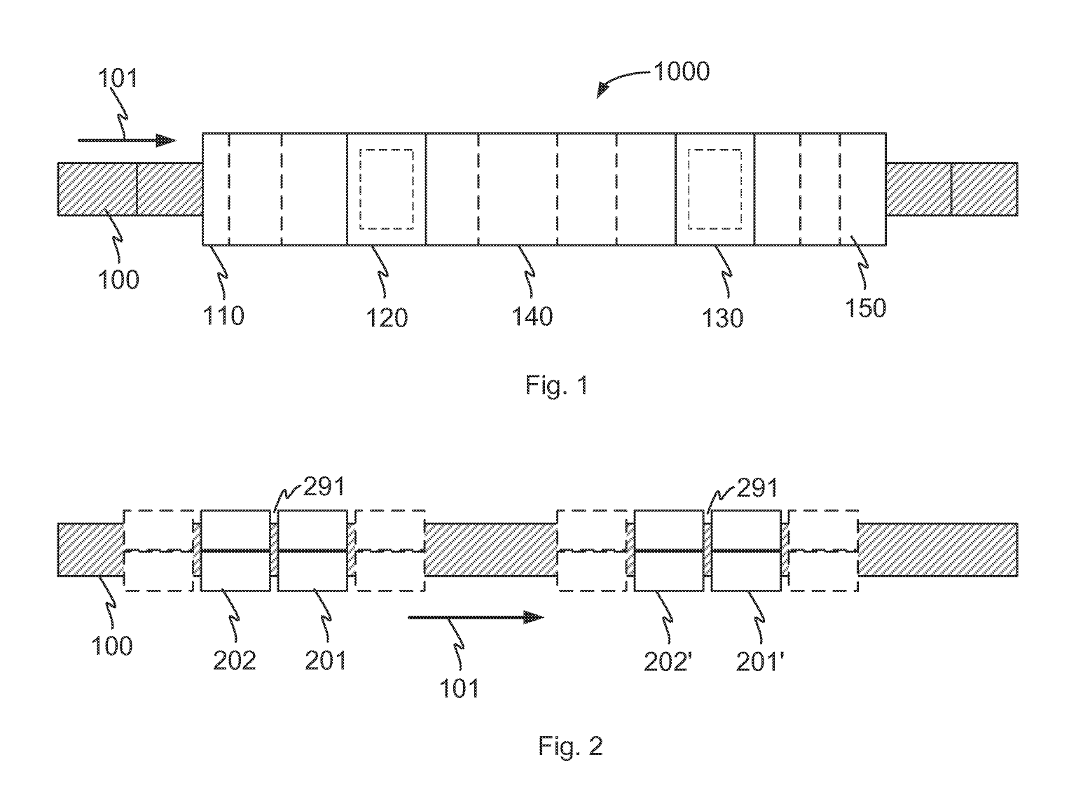

FIG. 1 is a simplified schematic diagram of an in-line thin-film deposition system according to an embodiment of the present invention. This diagram is merely an example, which should not unduly limit the scope of the claims herein. As shown, an in-line thin-film deposition system 1000 (simply called “system” in the later section of the specification) is illustrated schematically. The system 1000 is set up linearly (although some intermediate branches may be coupled in) with a series of vacuum compartments and associated lock/transfer compartments. Starting from an entry lock/transfer compartment 110, the system 1000 includes at least a first vacuum compartment 120, one or more intermediate compartments 140, and a second vacuum compartment 130, followed by an exit lock/transfer compartment 150. Note, the meaning of “first” or “second” is simply for reference convenience and does not limit it to actual physical location from either direction in the in-line system.

Additionally, the system 1000 includes a conveyer 100, in current example, linearly disposed through the whole system from entry to exit. The conveyer 100 is configured to support and transfer planar substrates (though it may be configured to transfer exotic shaped substrates) linearly from entry to exit, indicated by an arrow mark 101 in FIG. 1. It is configured to include a plurality of rollers (not visible here) for supporting the planar substrates loaded horizontally in a row one after another. The rollers are set at a certain speed to move the substrates, usually at a constant speed though it can be varied depending on process design throughout the system 1000.

In a specific embodiment, the system 1000 is configured to fabricate thin-film photovoltaic device and particularly to form its base electrode layer on a glass substrate. The first vacuum compartment 120 is designated for coating a barrier layer to wrap around the glass substrate for many technical advantages. For example, the glass substrate used in the system 1000 is soda lime glass and the corresponding barrier layer is a silicon oxide film made by sputtering a Silicon target in a reduced atmosphere environment with a controlled oxygen pressure. Specifically, the silicon oxide barrier layer is formed overlying the soda lime glass for preventing diffusion of certain unwanted impurities from the glass substrate into thin-film formed afterwards. One or more process conditions are designated to form a high-density silicon oxide film to be an effective barrier. For example, a silicon oxide barrier layer with a density of 1.1 g/cm³ or greater is desired. Preferably, the whole surfaces of the glass substrate should be fully wrapped by the barrier layer substantially without any scratches or broken regions. In an embodiment, the first vacuum compartment 120 is configured to sputter deposit the barrier layer on both top and bottom surfaces of a loaded planar substrate at a same time. The planar substrate is in motion by the conveyer 100 passing through the first vacuum compartment 120. In another embodiment, the first vacuum compartment 120 is configured to sputter deposit the barrier layer on just the top surface of the loaded planar substrate and is also configured to couple with one or more intermediate compartments 140 to reconfigure the planar substrate and reload the planar substrate on the conveyer 100 with the original bottom surface flipped to the top, then depositing the barrier layer overlying the bottom (now on top) surface. While, the terms of “top” or “bottom” are merely for description convenience, they should not limit the system or substrate loading within the system to one particular configuration. The horizontal loading scheme is merely an example and should be able to change into other orientations without leaving the scope covered by the claims herein.

Referring to FIG. 1, within the system 1000 the second vacuum compartment 130 is designated to grow a metal or other conductive material over the glass substrate that has been coated by a barrier layer to form a base electrode of a thin-film photovoltaic device. In particular, sputtering deposition technique is used to deposit molybdenum material from a molybdenum target disposed in the vacuum compartment. In an embodiment, the second vacuum compartment 130 is coupled to at least one intermediate compartment 140 from which the plurality of planar substrates are moved via the conveyer 100 in a row one after another. In another embodiment, the second vacuum compartment 130 should not be limited to just one chamber/compartment. In an implementation, depending on deposition condition and sample size, the molybdenum deposition may be accomplished by moving through two or more compartments respectively equipped with a molybdenum target with the same or modified composition to form a multi-layered molybdenum films with different properties, thicknesses, or compositions in different layers. Nevertheless, after the depositions each planar substrate is moved by the conveyer 100 through the exit transfer/lock 150 out of the system 1000.

FIG. 2 is simplified schematic diagram showing a row of planar substrates being moved by a conveyer associated with the in-line thin-film deposition system in FIG. 1 according to an embodiment of the present invention. This diagram is merely an example, which should not unduly limit the scope of the claims herein. As shown, a simplified top view of the conveyer 100 is configured to load a plurality of planar substrates in horizontal orientation and move them one after another. In a specific embodiment, each planar substrate is a rectangular shaped panel (see FIG. 2). For example, a 65×165 cm sized glass panel. As shown in FIG. 2, the conveyer 100 is configured to load a plurality of such planar substrates pair wisely in a row and each pair is loaded with a gap distance away from another pair next in the row. For example, a first pair of substrates 201 is followed by a second pair of substrates 202, between which a gap distance 291 exists. FIG. 2 schematically shows the conveyer 100 moves the plurality of planar substrates loaded horizontally in a row along the direction indicated by an arrow mark 101. The moving speed can be controlled, either constant of varied, depending on the process condition setting throughout the whole in-line deposition system 1000. The substrate moving speed also is associated the gap distance 291 between the loaded two neighboring pair of substrates. Due to certain process bottle neck throughout the system 1000, the gap distance 291 may be as large as several inches or several tens of inches. Of course, there are many variations, alternatives, and modifications. For example, the larger gap distance, not only causes slowed cycle time, but may cause other operation issues in molybdenum deposition process that are not expected when the gap distance is substantially smaller or the conveyer moving speed is much faster. More detail descriptions of the molybdenum sputtering process and system improvement according to the present invention are shown below.

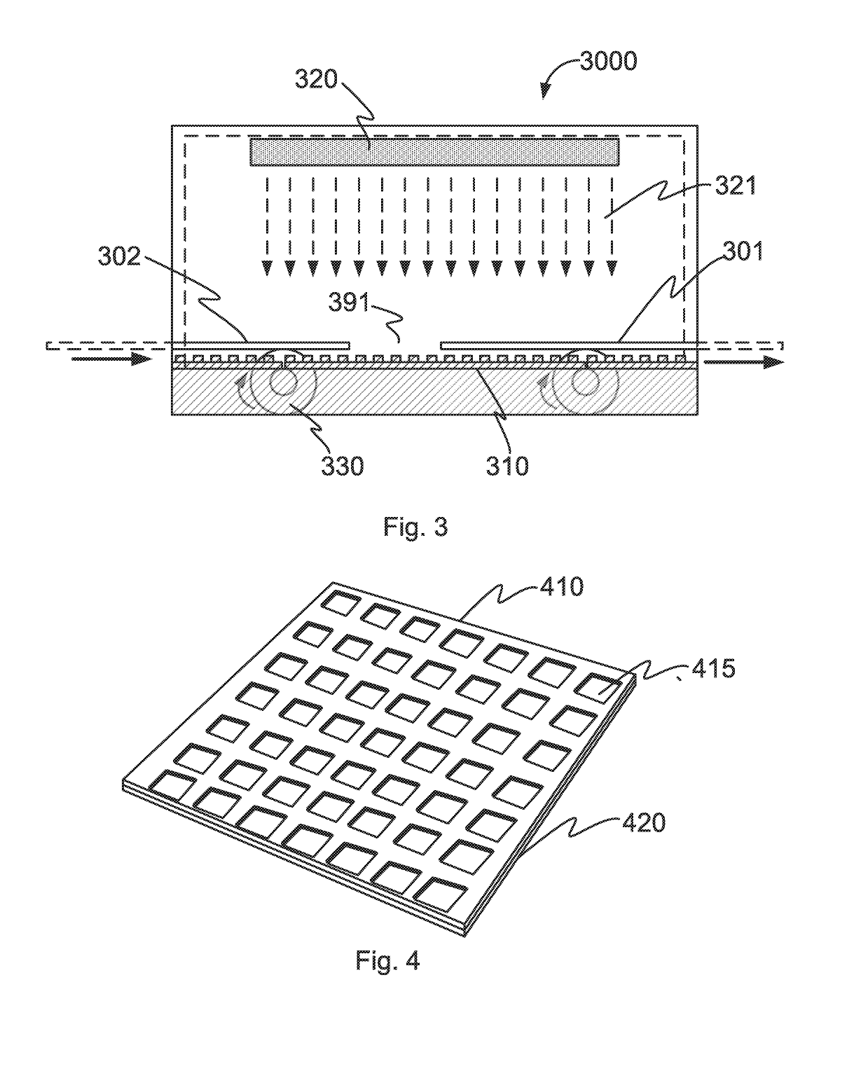

FIG. 3 is a simplified schematic diagram of a sputtering compartment with two moving planar substrates in load positions above a bottom shield according to an embodiment of the present invention. This diagram is merely an example, which should not unduly limit the scope of the claims herein. As shown, a sputtering chamber 3000 is schematically illustrated with one or more planar substrates moved by a moving device to pass under a sputtering target disposed in the chamber. In an embodiment, the sputtering chamber is one vacuum compartment of an in-line deposition system 1000 as shown in FIG. 1. In another embodiment, the sputtering chamber is a combination of several vacuum compartments coupled in a serial configuration in order to deposit a film over a large area of substrate or deposit multilayered film with alternative sputtering target, modified vacuum/working gas conditions, re-tuned bias conditions, film thickness adjustment, and more.

In an implementation of the present invention, the sputtering target 320 is a molybdenum target designated for forming a base electrode on the top surface of any loaded planar glass substrate 301 or 302 for fabricating a thin-film photovoltaic device. The sputtering target 320 is shown as an example to be in a square or rectangular shaped plate. It may also be made into a spherical shape or hemispherical shape, or others, disposed near a top region of the chamber 3000. A substrate moving device, which can be part of a conveyer 110 constructed for the whole in-line deposition system 1000, is operated through a plurality of rollers 330 disposed near a bottom region of the chamber 3000. Each roller 330 may be set partially above a bottom surface level of the chamber 3000 with a small spatial distance below the bottom surface of the moving substrate, allowing a free insertion of a bottom shield 310 in between. Each planar substrate, e.g., a soda lime glass substrate 301 or 302, has its bottom surface supported on the rollers 330 and its top surface subjected to the sputtering target 320 to receive a film deposition 321 therefrom while being moved (towards right in the figure) by the rolling rollers during a normal operation. Referring to description of the in-line deposition system, the bottom surface of each planar substrate has been coated with a barrier layer, now facing the bottom shied 310 below.

In a specific embodiment, any two neighboring loaded substrates has a gap distance 391, which also moves along with the moving substrates. In an example, the gap distance 391 between two large size (e.g., 65×165 cm) glass panels could be several inches to several tens of inches. As the gap 391 moves under the target 320 during the operation, a corresponding area of the bottom shield 310 is exposed to the target 320 and subjected to a partial film deposition 321 therefrom. The bottom shield 310 is thin plate disposed with intention to cover and protect the bottom member of the chamber 3000 as it can be removed easily during down time of the system for convenient system maintenance. Because of the exposure to the sputtering target due to the moving gap 391, the sputtered material, molybdenum in an example, is deposited and accumulated on the bottom shield 310.

Molybdenum is found to be relatively poor in adhesion on flat metal plate especially for irregularly interrupted deposition with constantly changed surface condition. Worst scenario of the accumulated sputtering molybdenum buildup is a formation of “molybdenum bubbles” so that one or more molybdenum pieces can grow abnormally due to peel off effect. Some of these abnormal molybdenum pieces may have their height near or even greater than the spatial distance between the bottom surface of the loaded planar substrate 301 and the top surface of the bottom shield 310. As the planar substrate is moved along, the barrier layer on the bottom surface of the planar substrate may be scratched or damaged by these abnormally-grown molybdenum pieces.

According to one or more embodiments of the present invention, the bottom shield 310 is configured to provide a corrugated upper surface to enhance adhesion of the sputtered material to suppress or substantially eliminate unwanted localized material buildup. As shown in FIG. 3, the upper surface region of the bottom shield 310 is made as a roughened or corrugated shape. The corrugated top surface region of the bottom shield 310 still is set to a certain distance (e.g., about 2 mm in one implementation) below a level of the bottom surface of the loaded planar substrate 301 or 302. This is not only to keep potential sputtering material buildup on the bottom shield away from the bottom surface of the substrate, but also is to ensure better adhesion of molybdenum film on the bottom shield to substantially prevent the formation of any abnormal molybdenum pieces from causing damages to the barrier layer on the bottom surface of each planar substrate.

In an embodiment, the corrugated top region includes a plurality of roughened surface features having a character lateral dimension of about 2 mm and a depth of about 2 mm or greater, which is found to be very effective to cause the sputtering molybdenum material to be adhere on the top region. For example, as shown in FIG. 6, the upper surface region of the bottom shield 620 is roughened with a plurality of protruded small islands 610 or shaped textures across the entire area. Each island or texture 610 can be configured to have desired feature dimension (for example, about 1 or 2 mm) that has an optimized adhesion effect for the sputtering molybdenum material. Of course, some variations in the selections of the roughened surface features exist and can be further optimized in their shapes or dimensions. But it should be in the escape the scope of the present invention.

In a specific embodiment, the bottom shield 310 disposed to cover the bottom member of the sputtering chamber 3000 is a two-piece plate. A first piece is a thin flat plate including a plurality of through-holes and is placed directly over a second piece that simply is a flat solid plate. The plurality of through-holes is distributed across the whole area of the first piece and each through-hole, can be in any shape, has a feature lateral dimension of about 2 mm and the plate thickness is about 2 mm or greater. Effectively, the first piece of plate having the plurality of through-holes is performed like a grating structure. The first piece of the two-piece plate is directly exposed to the incoming sputtering molybdenum material and through-holes allow some molybdenum coating to penetrate therein to effectively improve adhesion both locally and anchoring of the film across the first piece of the two-piece plate. The second piece of two-piece plate is a solid piece for preventing any spray-thru of molybdenum deposition. The improved adhesion of the molybdenum material through the two-piece shield structure can help to substantially prolong the process life time by reducing the potential of accumulation abnormal material buildup on the bottom shield and removing dangers of barrier layer damages caused by molybdenum peel off effect.

FIG. 4 is a simplified diagram illustrating the two-piece bottom shield disposed in the Mo-deposition compartment according to an embodiment of the present invention, As shown, the bottom shield is a bi-layer structure having a top flat plate 410 characterized by a perforated plate with a plurality of through-holes 415 and a bottom flat plate 420 being fully solid. The through-holes are just shown in a square shape although they can be actually in any shape. The lateral size of these through-holes can be about 2 mm which is also roughly the spacing between the holes and the thickness of the top plate. The top plate's perorated structure acts as a grating structure to facilitate absorption of the incoming molybdenum atoms (or ions) from sputtering target. The bottom solid plate still provides protection for the bottom member of the sputtering compartment. The bi-layer bottom shield substantially improves the up-time of the whole system by substantially eliminating the film peel-off effect due to abnormal material buildup by molybdenum deposition. The system maintenance can be delayed to improve production yield while still can be easily done with the removable bi-layer bottom shield.

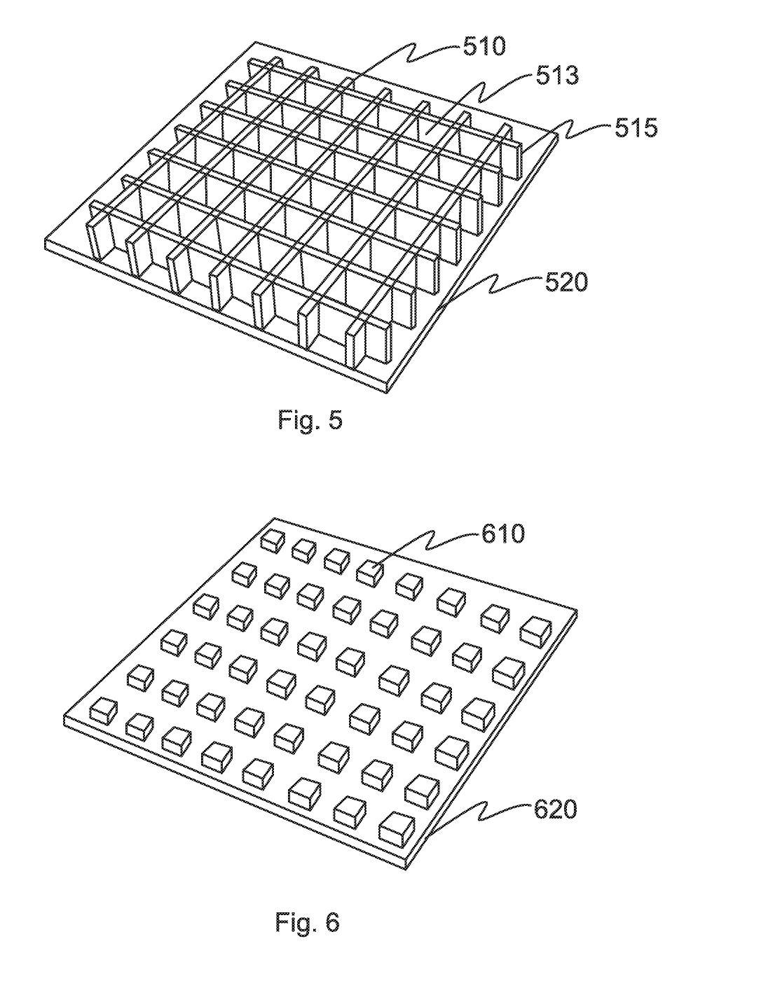

In an alternative example, FIG. 5 shows a slightly different structure of a double-layered Shield. The first layer 510 is a grid structure having a plurality of holes 513 and frames 515. The second layer 520 is a solid plate. The feature sizes of these grid-holes and frames and the height of the grid structure can be optimized (not shown in true scale just for viewing convenience) based on the effectiveness of sputtering material adhesion. As mentioned above, the grid-holes may be made around 1 to 2 mm in size and the frame width is more or less the same as the hole size. The height of the grid structure (or the thickness of the first plate) is about 2 mm or greater. Of course, there are many variations, alternatives, and modifications. FIG. 6 shows another embodiment of the present invention with a single-layered shield 620 with roughened surface region 610. The roughened surface structure can be a plurality of shaped islands or bumps or other mechanical textures. Between them there are channel spacings laterally in same size. These roughened surface structures can help to retain the deposited molybdenum film to be absorbed within the channels to avoid un-wanted buildup to cause film peel off and further to cause damage of the barrier layer on the bottom side of the substrate.

It is also understood that the examples, figures, and embodiments described herein are for illustrative purposes only and that various modifications or changes in light thereof will be suggested to persons skilled in the art and are to be included within the spirit and purview of this application and scope of the appended claims.

What is claimed is:

1. An in-line sputtering system for the manufacture of thin film solar devices, the system comprising:
a first vacuum compartment configured to grow a barrier layer overlying both top and bottom surfaces of a first planar substrate;
a conveyer comprising a plurality of rollers configured to move a plurality of planar substrates loaded horizontally in a row through the first vacuum compartment, the plurality of planar substrates including the first planar substrate with at least a gap distance away from a second planar substrate next in the row on the conveyer;
a second vacuum compartment configured to receive the plurality of planar substrates including the first and the second planar substrates from the first vacuum compartment, each of the plurality of planar substrates having its bottom surface being supported by the rollers to move horizontally under a molybdenum target to have its top surface being coated by a molybdenum layer;
a bottom shield disposed on entire bottom region of the second vacuum compartment except a few places for the rollers;
wherein the bottom shield comprises a corrugated surface region subjecting to deposition from the molybdenum target whenever the gap distance between any neighboring planar substrates moves over the bottom shield, the corrugated surface region being configured to adhere substantially the deposited molybdenum layer free of any peel-off effect.

2. The system of claim 1 wherein the corrugated surface region comprises a plurality of roughened features each characterized by a height of about 2 mm or greater and a lateral dimension of about 2 mm.

3. The system of claim 1 wherein the bottom shield comprises a two-piece plate including a first plate removably placed over a second plate, the first plate comprising the corrugated surface region and the second plate comprising a flat solid.

4. The system of claim 3 wherein the first plate comprises a plurality of holes have a lateral dimension of about 2 mm and a thickness of about 2 mm or greater, serving like a grating over the second plate.

5. The system of claim 1 wherein the barrier layer formed on the bottom surface of any of the plurality of planar substrates comprises silicon oxide characterized by a density of about 1.1 g/cm³ or higher.

6. The system of claim 5 wherein the barrier layer on the bottom surface of any planar substrate faces the bottom shield in the second vacuum compartment and is substantially free from being scratched by any molybdenum material built up due to peel off effect from the bottom shield.

7. The system of claim 1 further comprising at least one intermediate compartment for receiving each of the plurality of planar substrates, flipping over, and re-loading each of the plurality of planar substrates horizontally on the conveyer with at least the gap distance away from a next planar substrate in a row, the plurality of planar substrates being moved in the row by the conveyer towards the second vacuum compartment.

8. An in-line sputtering system comprising:
a chamber;
a sputtering target near a top region of the chamber;
a moving device located on a bottom region of the chamber, the moving device being configured to move a plurality of planar substrates loaded horizontally in a row with at least a gap distance between any neighboring substrates, the gap distance allowing the bottom region to be subjected to a deposition from the sputtering target as the gap distance moves across the entire bottom region along with the plurality of planar substrates by the moving device; and
a bottom shield disposed to cover entire bottom region except the moving device and configured to adhere the deposition through the gap distance from the sputtering target for preventing a deposition buildup.

9. The system of claim 8 wherein the chamber comprises one or more vacuum compartments belonging to an in-line sputtering system for manufacturing copper-indium-gallium-diselenide-based photovoltaic devices.

10. The system of claim 8 wherein the sputtering target is a molybdenum target.

11. The system of claim 8 wherein the bottom shield comprises a two-piece plate including a first piece removablely placed on a second piece, the first piece comprising a perforated plate having a plurality of through-holes characterized by a lateral dimension of about 2 mm and a thickness of about 2 mm or greater, the second piece comprising a flat solid plate.

12. The system of claim 8 wherein the bottom shield comprises a plurality of roughened surface features characterized by a lateral dimension of about 2 mm and a depth of about 2 mm or greater.

13. The system of claim 8 wherein each of the plurality of planar substrates comprises a soda lime glass having a thin film coated on both its top and bottom surfaces before being moved into the chamber by the moving device.

14. The system of claim 13 wherein the bottom shield is disposed at least 2 mm below the bottom surface of any planar substrate supported on the moving device.

15. The system of claim 13 wherein the thin film coated on the bottom surface of any planar substrate is substantially free from being scratched by any buildup of the deposition on the bottom shield.
